(19) United States
(12) Patent Application Publication
(10) Pub. No.: US 2021/0066053 A1
(43) Pub. Date: Mar. 4, 2021

(54) ANNULAR MEMBER, SUBSTRATE PROCESSING APPARATUS AND METHOD OF CONTROLLING SUBSTRATE PROCESSING APPARATUS

(71) Applicant: Tokyo Electron Limited, Tokyo (JP)

(72) Inventors: Hiroshi NAGAIKE, Miyagi (JP); Naoki SUGAWA, Miyagi (JP)

(21) Appl. No.: 16/999,451

(22) Filed: Aug. 21, 2020

(30) Foreign Application Priority Data
Sep. 4, 2019 (JP) 2019-161499

(51) Int. Cl. H01J 37/32; H01L 21/67; H01L 21/66; H01L 21/683

(52) U.S. Cl. CPC H01J 37/32642; H01L 21/67069; H01L 21/67253; H01J 2237/334; H01L 21/6833; H01J 37/32972; H01L 22/26

(57) ABSTRACT

An annular member includes an annular member body to be disposed around a substrate in a substrate processing apparatus. A heterogeneous material portion is disposed in the annular member body and formed of a heterogeneous material different from a material of the annular member body.

### CROSS-REFERENCE TO RELATED APPLICATION

The present application is based on and claims priority to Japanese Priority Application No. 2019-161499 filed on Sep. 4, 2015, the entire contents of which are hereby incorporated herein by reference.

### BACKGROUND OF THE INVENTION

### 1. Field of the Invention

The present disclosure relates to an annular member, a substrate processing apparatus and a method of controlling a substrate processing apparatus.

### 2. Description of the Related Art

In a processing apparatus that performs desired processing, such as etching, on a substrate, a mounting stage that adsorbs the substrate is known.

The U.S. Pat. No. 10,041,868 discloses a method of detecting edge ring wear by providing a microchamber on the edge ring and detecting a hole by imaging the edge ring with a borescope.

### SUMMARY OF THE INVENTION

In one aspect, the present disclosure provides an annular member, a substrate processing apparatus, and a method for controlling a substrate processing apparatus that can detect wear and tear.

In order to solve the above problem, according to one aspect, there is provided an annular member that includes an annular member body to be disposed around a substrate in a substrate processing apparatus. A heterogeneous material portion is disposed in the annular member body and formed of a heterogeneous material different from a material of the annular member body.

Additional objects and advantages of the embodiments are set forth in part in the description which follows, and in part will become obvious from the description, or may be learned by practice of the disclosure. The objects and advantages of the disclosure will be realized and attained by means of the elements and combinations particularly pointed out in the appended claims. It is to be understood that both the foregoing general description and the following detailed description are exemplary and explanatory and are not restrictive of the disclosure as claimed.

### BRIEF DESCRIPTION OF THE DRAWINGS

FIG. 1 is a cross-sectional view illustrating an example of a substrate processing apparatus according to an embodiment;

FIGS. 2A to 2C are diagrams illustrating enlarged cross-sectional views of an edge ring according to an example;

FIG. 3 is a graph showing an example of detection results of a detector in an example of an edge ring;

FIGS. 4A to 4C are schematic diagrams of partially enlarged cross sections near an edge ring according to another example;

FIG. 5 is a graph showing an example of detection results of a detector in an edge ring according to another example;

FIGS. 6A to 6G are one-sided cross-sectional views of edge rings according to another example; and

FIGS. 7A to 7C are examples of plan views of edge rings.

### DETAILED DESCRIPTION OF THE PREFERRED EMBODIMENTS

Hereinafter, embodiments of the present disclosure will be described with reference to the drawings. In each drawing, the same components are indicated by the same reference numerals and overlapping descriptions may be omitted.

### Plasma Processing Apparatus

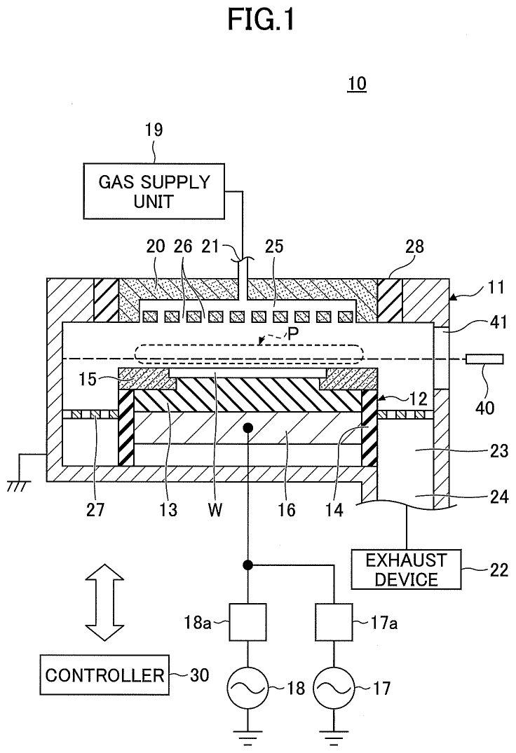

A plasma processing apparatus (substrate processing apparatus) 10 according to an embodiment will be described with reference to FIG. 1. FIG. 1 shows a cross-sectional schematic diagram of a parallel plate type capacitively coupled plasma (CCP) processing apparatus 10 as an example of a plasma processing apparatus 10 according to an embodiment.

First, the configuration of the plasma processing apparatus 10 shown in FIG. 1 will be described. The plasma processing apparatus 10 includes a processing chamber 11 and a mounting stage 12 disposed therein. The processing chamber 11 is a cylindrical chamber, for example, made of aluminum with an alumited surface (anodizing treatment), and is grounded. The mounting stage 12 has a base 16 and an electrostatic chuck 13 positioned above the base 16. The mounting stage 12 is disposed at the bottom of the processing chamber 11 via an insulating member retainer 14.

The base 16 is formed of aluminum or the like. The electrostatic chuck 13 is formed of a dielectric such as alumina (Al₂O₃) and has a mechanism for holding the wafer W with electrostatic adsorption force. In the electrostatic chuck 13, a wafer W is disposed in the center, and an annular edge ring 15 (also referred to as a focus ring) surrounding the wafer W is disposed in the outer circumference. In other words, the annular edge ring 15 is disposed around the wafer W in the processing chamber 11 of the plasma processing apparatus 10 and placed on the electrostatic chuck 13.

An annular exhaust path 23 is formed between the side wall of the processing chamber 11 and the side wall of the mounting stage 12 and is connected to an exhaust device 22 via an exhaust port 24. The exhaust device 22 is constituted of a vacuum pump such as a turbomolecular pump and a dry pump. The exhaust device 22 directs the gas in process chamber 11 to the exhaust path 23 and the exhaust port 24 and evacuates the gas. This reduces the pressure of the process space in the process chamber 11 to a predetermined degree of vacuum.

The exhaust path 23 includes a baffle plate 27 that separates the processing space from the exhaust space and controls the flow of gas. The baffle plate 27 is, for example, an annular member coated with a corrosion-resistant membrane (e.g., yttrium oxide (Y₂O₂)) on the surface of a base material formed of aluminum, and having a plurality of through-holes formed therein.

The mounting stage 12 is connected to a first radio frequency power supply 17 via a matching box 17a and to a second radio frequency power supply 18 via a matching device 18a. The first radio frequency power supply 17 supplies, for example, 60 MHz of radio frequency power for plasma generation (hereinafter referred to as “HF power”) to the mounting stage 12. The matching device 17a has a matching circuit for matching the impedance of the load side (mounting side) to the output impedance of the first radio frequency power supply 17. The second radio frequency power supply 18 supplies, for example, 40 MHz of radio frequency power for ion retraction (hereinafter referred to as “LF power”) to the mounting stage 12. The matching box 18a has a matching circuit for matching the impedance of the load side (mounting side) to the output impedance of the second radio frequency power supply 18. Thus, the mounting stage 12 also functions as a lower electrode.

The ceiling opening of the processing chamber 11 includes a showerhead 20 circumferentially through a ring-shaped insulating member 28. The HF power is supplied capacitively between the mounting stage 12 and the showerhead 20, and plasma is produced from the gas primarily by the HF power.

The ions in the plasma are drawn into the mounting stage 12 by LF power supplied to the mounting stage 12, and collide with the wafer W mounted on the mounting stage 12, thereby efficiently etching and the like a predetermined film on the wafer W.

The gas supply 19 supplies gas according to the process conditions of each of the plasma processing steps, such as an etching process, a cleaning process, and a seasoning process. A gas enters the showerhead 20 via a gas line 21 and is introduced into the processing chamber 11 in a shower-like manner from a number of gas discharge holes 26 via a gas diffusion chamber 25.

The controller 30 has a CPU, ROM (Read Only Memory), and RAM (Random Access Memory). The controller 30 controls various plasma processing processes and controls the entire apparatus according to the procedure set in the recipe stored in the RAM.

When performing plasma processing in the plasma processing apparatus 10 of such construction, the wafer W is first carried into the processing chamber 11 from a gate valve, not shown in the drawing, held on a transport arm. The wafer W is placed on the electrostatic chuck 13. The gate valve is closed after the wafer W is carried in. By applying a DC voltage to the electrodes (not shown in the drawings) of the electrostatic chuck 13, the wafer W is adsorbed and held on the electrostatic chuck 13 by coulomb forces.

The pressure in the process chamber 11 is reduced to a set value by the exhaust device 22 and the interior of the process chamber 11 is controlled to be in a vacuum state. A predetermined gas is introduced into the processing chamber 11 from the showerhead 20 in a shower-like manner. The HF power and the LF power are supplied to the mounting stage 12. In FIG. 1, because the HF power is supplied to the mounting stage 12, a plasma generation region P is in the vicinity of the wafer W.

The plasma is generated from the introduced gas, principally by the HF power, and plasma processing, such as etching the wafer W, is performed by the action of the plasma. After the plasma process is completed, the wafer W is retained on the transport arm and is carried out of the process chamber 11. By repeating this process, the wafer W is processed successively.

Light emitted within processing chamber 11 during plasma processing of the wafer W is incident on a detector 40 via a window 41 on the sidewall. The optical axis of detector 40 is positioned to pass through the plasma generation region P near the wafer W.

The detector 40 detects products resulting from heterogeneous materials of the edge ring 15, which will be discussed later. For example, the detector 40 is an emission spectrometer that monitors the state of the plasma using OES (Optical Emission Spectroscopy). In OES, the element of interest in the sample is vaporized and excited by discharged plasma, and the wavelength of the obtained element's unique bright line spectrum (atomic spectrum) is qualitatively determined, and quantitation is made from the luminescence intensity. However, OES is an example of a technique for monitoring plasma conditions, and the detector 40 is not limited to OES if it can monitor plasma conditions.

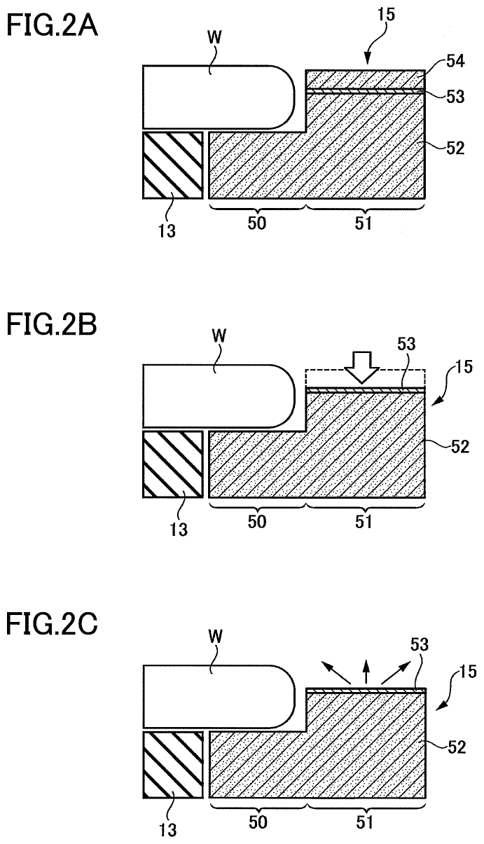

Next, an example of an edge ring 15 provided by the plasma processing apparatus 10 according to an embodiment will be described with reference to FIGS. 2A to 2C. FIGS. 2A to 2C are enlarged cross-sectional views illustrating an edge ring 15 according to an example.

As illustrated in FIG. 2A, the edge ring 15 is an annular member having a multi-stage cross-section. The edge ring 15 has an inner ring portion 50 and an outer ring portion 51. The inner ring portion 50 has a circular shape. The outer ring portion 51 is integrally formed on the outside of the inner ring portion 50 in a radial direction and has a circular shape. The bottom surface of the inner ring portion 50 is coincident with the bottom surface of the outer ring portion 51. The top surface of the inner ring portion 50 is lower than the top surface of the outer ring portion 51. As illustrated in FIG. 2A, when the wafer W and the edge ring 15 are mounted on the electrostatic chuck 13 of the mounting stage 12, the inner ring portion 50 is positioned below the outer edge of the wafer W, and the outer ring portion 51 is positioned radially outward of the wafer W.

The outer ring portion 51 has a base part 52, a marker layer 53 and an upper layer 54. The base part 52 is integrally formed with the inner ring portion 50. The marker layer 53 is formed over the substrate 52. The upper layer 54 is formed over the marker layer 53. Here, the inner ring portion 50, the bae part 52, and the upper layer 54 are formed, for example, of silicon. The marker layer 53 is formed of a different heterogeneous material (e.g., tungsten) than silicon. In other words, the edge ring 15 is formed of silicon, and the marker layer 53 formed of a different heterogeneous material (e.g., tungsten) than silicon is embedded in the outer ring portion 51.

Here, the plasma processing apparatus 10 performs an etching process for etching the wafer W or a cleaning process for cleaning the inside of the processing chamber 11 during the wafer W processing. As illustrated in FIG. 2B, the upper layer 54 provided on the top surface of the outer ring portion 51 is etched and consumed by the etching and cleaning processes. In FIG. 2B, the etching direction is indicated by a blank arrow. Another protective member (not shown in the drawing) is disposed on the outer peripheral side of the edge ring 15, and etching from the outer cylindrical surface of the outer ring portion 51 is reduced.

As illustrated in FIG. 2C, when the upper layer 54 of the outer ring portion 51 is further etched and consumed, the marker layer 53 is exposed on the upper surface of the outer ring portion 51. The exposure of the marker layer 53 etches the marker layer 53 and generates a product due to the heterogeneous material of the marker layer 53. In FIG. 2C, the generation of a product caused by a different material is indicated by black arrows.

The products due to heterologous materials emit radical light in the plasma generation region P. Here, the detector 40, which is the emission spectroscopic analyzer illustrated in FIG. 1, detects radical emissions due to heterogeneous materials of the marker layer 53 by monitoring the emission of etching plasma generated in the plasma generation region P in the processing chamber 11 through the spectrometer. The detection result of the detector 40 is sent to the controller 30. The controller 30 determines whether or not the detector 40 detects radical emissions due to heterogeneous materials of the marker layer 53. If a radical emission due to a heterogeneous material of the marker layer 53 is detected, the edge ring 15 is determined to be depleted. Thus, according to the plasma processing apparatus 10 in accordance with an embodiment, wear of the edge ring 15 can be monitored without removing the edge ring 15 from the processing chamber 11.

For example, metals (e.g., W, Al, Fe (SUS), Co, Ni), metal oxides, metal nitrides, semiconductors, and the like can be used as heterogeneous materials to form the marker layer 53.

Here, the heterologous material forming the marker layer 53 is different from at least silicon, which is the main material of the edge ring 15.

Further, in the processing of the plasma processing apparatus 10, the product resulting from the heterologous material of the marker layer 53 is different from the product resulting from the main material of the edge ring 15. That is, the heterologous material that forms the marker layer 53 preferably uses a material that is different from the material that produces the same product (e.g., SiF₄) as the product resulting from the main material (Si) of the edge ring 15, such as SiO₂, SiN. It should be noted that in addition to the same product as the product resulting from the main material (Si) of the edge ring 15 (e.g., SiF₄), such as a metal silicide (e.g., tungsten silicide), a material that generates a product different from the product resulting from the main material (Si) of the edge ring 15 (e.g., WF₅) can be used as a heterologous material forming the marker layer 53.

Preferably, the heterologous material forming the marker layer 53 is selected from a material different from the surface material (e.g. Y₂O₃, YF, AlO₃) of the wafer W and the member to be exposed to the plasma in the processing chamber 11. Thus, the background value can be reduced when detecting the product caused by the heterologous materials in the marker layer 53, thereby improving the detection performance by the detector 40. Further, in the processing of the plasma processing apparatus 10, the product resulting from the heterologous material of the marker layer 53 is different from the material resulting from the surface material.

The heterologous material forming the marker layer 53 is preferably selected from a material that is etched in the processing of the plasma processing apparatus 10. This allows the detector 40 to detect that the top surface of the outer ring portion 51 of the marker layer 53 has been exposed, that is, the top surface of the outer ring portion 51 of the edge ring 15 has been consumed. That is, the state of the edge ring 15 can be detected without removing the edge ring 15 from the processing chamber 11.

In addition, when a material having a lower etch rate is used as the heterologous material forming the marker layer 53 than the etch rate of the main material forming the edge ring 15, the generation of a product due to the heterogeneous material of the marker layer 53 can be inhibited, thereby reducing the influence on the processing on the wafer W.

Also, if the heterologous material forming the marker layer 53 uses a material having a high etch rate as compared to the main material forming the edge ring 15, the detection by the detector 40 can be improved and the wear of the edge ring 15 can be detected quickly.

It should be noted that the detector 40 is described as being an optical emission spectrometer (OES) that monitors the etching plasma generated in the plasma generation region P in the processing chamber 11, but is not limited thereto.

For example, the detector 40 may be a self-plasma emission spectrometer (OES). In this case, the detector 40 is connected via a tube (not shown in the drawing) that draws the gas components. The connection position may be a position in communication with the plasma generation region P (upstream of the baffle plate 27). The connection position may be the exhaust path 23 (downstream of the baffle plate 27). The connection position may be an exhaust line (not shown in the drawing) downstream of the exhaust device 22.

The detector 40, which is a self-plasma generation emission spectrometer, draws a gas through a tube. The detector 40 also generates its own plasma suitable for instrumentation and monitors the components of the drawn gas through the spectrometer. The detector 40 detects radical emissions resulting from products (gases) caused by heterogeneous materials. Thus, the controller 30 can determines whether or not the edge ring 15 has been consumed. Also, by using a self-plasma generation emission spectrometer as the detector 40, the degree of freedom of design of the mounting position of the detector 40 can be improved.

For example, the detector 40 may be a quadrupole mass spectrometer (QMS). In this case, the detector 40 is connected via a tube (not shown in the drawing) that: draws the gas components. The connection position may be a position in communication with the plasma generation region P (upstream of the baffle plate 27). The connection position may be the exhaust: path 23 (downstream of the baffle plate 27). The connection position may also be an exhaust line (not shown in the drawing) downstream of the exhaust 22.

The detector 40, a quadrupole mass spectrometer, draws a gas through a tube. The detector 40 can also detect wear and tear of the edge ring 15 by monitoring a mass number of molecules corresponding to a product caused by a different material.

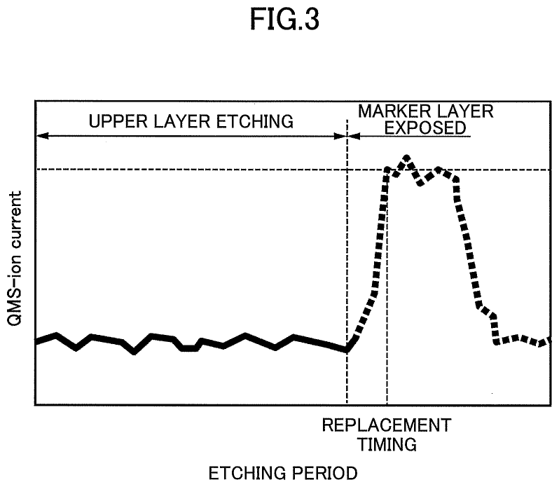

FIG. 3 is a graph illustrating an example of a detection result of a detector 40 at an edge ring 15 according to an example. FIG. 3 shows the results using a quadrupole mass spectrometer as the detector 40. In FIG. 3, the horizontal axis indicates time (etching time) and the vertical axis indicates a detection value when a mass number corresponding to a product caused by a different material is monitored.

For example, a case where tungsten is used as a heterogeneous material of the marker layer 53 and a gas containing fluorine is used as an etching gas will be described. Tungsten is etched, thereby producing WF₅ gas. A quadrupole mass spectrometer, which is the detector 40, detects WF₅ gas (molecular weight 279).

As shown in the graph of FIG. 3, the detection value of the detector 40 does not increase while the upper layer 54, shown by a solid line, is etched. On the other hand, the exposure and etching of the marker layer 53 shown by a dashed line increases the detection value of the detector 40. Thus, the controller 30 can determine that the edge ring 15 has been consumed when the detected value of the detector 40 exceeds a predetermined threshold value.

For example, the detector 40 may be an infrared absorption spectrometer (IR). In this case, the detector 40 is connected via a tube (not shown in the drawing) that draws gas components in the etching plasma. The connection position may be a position in communication with the plasma generation region P (upstream of the baffle plate 27). The connection position may be the exhaust path 23 (downstream of the baffle plate 27). The connection position may be an exhaust, line (not shown in the drawing) downstream of the exhaust 22.

The detector 40, which is an infrared absorption spectrometer, draws a gas through a tube. The detector 40 also monitors the absorption of light corresponding to the product caused by a different material, from the light incident from the light source and transmitted light transmitted through the gas. Thus, the controller 30 can determine that the edge ring 15 has been consumed based on the detection result of the detector 40.

It should be noted that the timing of detecting the wear of the edge ring 15 using the detector 40 may be set during the process (etching process) of the wafer W. It may be performed between processes of the wafer W. It may also be performed during the wafer-less dry cleaning process performed during the wafer W processes. It may be performed during the dry cleaning process after a predetermined number of wafers W are processed.

When it is determined that the edge ring 15 is consumed, the controller 30 may determine that maintenance needs to be performed in the process chamber 11. For example, the controller 30 directs maintenance of the edge ring 15. Thus, the timing of the maintenance of the edge ring 15 can be appropriately determined. Maintenance of the edge ring 15 may be performed by replacing the consumed edge ring 15 by a new edge ring 15. The maintenance of the edge ring 15 may be accomplished by repairing the consumed portion. For example, the consumed portion may be repaired by forming the upper layer 54 by a deposition process on the top surface of the outer ring portion 51 of the edge ring 15. When the consumed portion is non-uniform, the upper layer 54 may be formed by the deposition process after the unwanted portion (the remainder of the consumed upper layer 54) is removed. This allows the edge ring 15 to be reused, thereby reducing maintenance costs.

The controller 30 may change the recipe of the process (etching process) of the wafer W when it is determined that the edge ring 15 has been consumed. For example, when the height, of the upper surface of the outer ring portion 51 of the edge ring 15 is reduced, a step difference occurs between the sheath on the wafer W and the sheath on the edge ring 15. As a result, a tilting phenomenon occurs in which the incident angle of ions changes at the outer edge of the wafer W and the hole and the interconnection pattern are tilted.

For example, the plasma processing apparatus 10 may include an elevator (not shown in the drawing) for raising and lowering the edge ring 15. In this configuration, when it is determined that the edge ring 15 has been consumed, the controller 30 raises the edge ring 15 by an amount corresponding to the consumed thickness of the edge ring 15 through the elevator (not shown in the drawing). This allows the sheath on the wafer W and the sheath on the edge ring 15 to be flat, thereby returning the incident angle of ions to the wafer W to a state before the edge ring 15 is consumed, thereby reducing the tilting phenomenon.

For example, the plasma processing apparatus 10 may include a voltage applying portion (not shown in the drawing) for applying a DC voltage to the edge ring 15. In this configuration, the controller 30 applies a voltage to the edge ring 15 when it is determined that the edge ring 15 has been consumed. This allows the sheath on the wafer W and the sheath on the edge ring 15 to be flat, thereby returning the incident angle of ions to the wafer W to a state before the edge ring 15 is consumed, thereby reducing the tilting phenomenon.

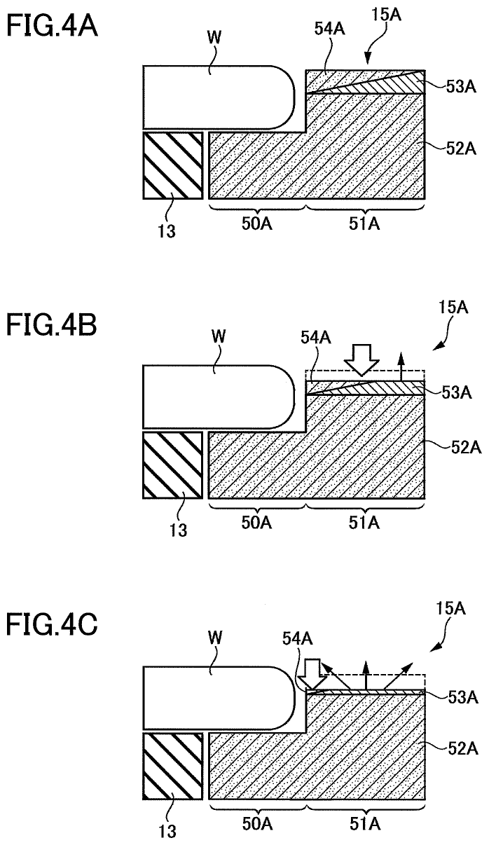

Next, another example of an edge ring 15 provided by the plasma processing apparatus 10 according to one embodiment will be described with reference to FIGS. 4A to 4C. FIGS. 4A to 4C are partially enlarged cross-sectional views illustrating an edge ring 15A according to another example.

As illustrated in FIG. 4A, the edge ring 15A is an annular member having a multi-stage cross-section. The edge ring 15A has an inner ring portion 50A and an outer ring portion 51A. The inner ring portion 50A has a circular shape. The outer ring portion 51A is integrally formed on the outside of the inner ring portion 50A in a radial direction, and has a circular shape. The bottom surface of the inner ring portion 50A and the bottom surface of the outer ring portion 51A coincide with each other. The top surface of the inner ring portion 50A is lower than the top surface of the outer ring portion 51A. As illustrated in FIG. 4A, when the wafer W and the edge ring 15A are mounted on the electrostatic chuck 13 of the mounting stage 12, the inner ring portion 50A is positioned below the outer edge of the wafer W and the outer ring portion 51A is positioned radially outward of the wafer W.

The outer ring portion 51A has a base part 52A, a marker layer 53A and an upper layer 54A. The base part 52A is formed integrally with the inner ring portion 50A. The marker layer 53A is formed on the substrate 52A. The upper layer 54A is formed over the marker layer 53A. Here, the inner ring portion 50A, the base part 52A, and the upper layer 54A are formed, for example, of silicon. The marker layer 53A is formed of a different heterogeneous material (e.g., tungsten) than silicon. In other words, the edge ring 15A is formed of silicon, and the marker layer 53A formed of a different heterogeneous material (e.g., tungsten) than silicon is embedded in the outer ring portion 51A.

Here, the marker layer 53A of the edge ring 15A is formed so as to widen horizontally from the top surface of the outer ring portion 51A in a depth direction.

As illustrated in FIG. 4B, an etching or cleaning process etches and wears the upper layer 54A on the top surface of the outer ring portion 51A, exposing a portion of the marker layer 53A on the top surface of the outer ring portion 51A. In FIG. 4B, the etching direction is indicated by a blank arrow. Products from different materials are generated. Exposure of a portion of the marker layer 53A etches the marker layer 53A and generates products caused by heterologous materials of the marker layer 53A. Incidentally, in FIG. 4B, the generation of a product caused by a different material is indicated by a black arrow.

As illustrated in FIG. 4C, the area of the marker layer 53A exposed on the top surface of the outer ring portion 51A also increases as the upper layer 54A of the outer ring portion 51A is further etched and consumed. As the exposed area of the marker layer 53A increases, the generation of products caused by heterogeneous materials also increases. Thus, the consumed thickness of the edge ring 15 can be detected depending on the amount of the generated product.

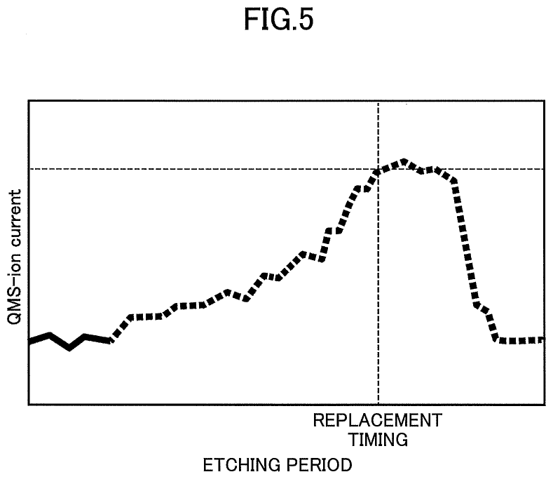

FIG. 5 is a graph illustrating one example of a detection result of a detector 40 at an edge ring 15A according to another example. FIG. 5 shows the result using a quadrupole mass spectrometer as the detector 40. In FIG. 5, the horizontal axis indicates time (etching time) and the vertical axis indicates a detection value when a mass number corresponding to a product caused by a different material is monitored.

As shown in the graph of FIG. 5, the detection value of the detector 40 does not increase while the upper layer 54, shown by a solid line, is etched. In contrast, the marker layer 53A shown by a dashed line is exposed and etched, by which the detection value of the detector 40 gradually increases. Thus, the controller 30 can determine that, the edge ring 15 has been consumed when the detected value of the detector 40 exceeds a predetermined threshold value. Also, the degree of wear on the edge ring 15 can be detected.

Further, the processing may be changed according to the detection result of the detected value. For example, if the detected value of the detector 40 exceeds a first threshold, the controller 30 raises the edge ring 15 using an elevator (not shown in the drawing) that raise the edge ring 15 by an amount corresponding to the consumed thickness of the edge ring 15. When the detected value of the detector 40 exceeds a second threshold value greater than the first threshold value, the controller 30 applies a voltage to the edge ring 15 using a voltage applying portion (not shown in the drawing) that applies a DC voltage to the edge ring 15. This allows the sheath on the wafer W and the sheath on the edge ring 15 to be flat, while returning the incident angle of the ions onto the wafer W to a state before the edge ring 15 is consumed. When the detection value of the detector 40 exceeds a third threshold that is greater than the second threshold, the controller 30 may determine that the edge ring 15 should be replaced.

The controller 30 may record the time from the installation of the new edge ring 15 to the detection of a product caused by a heterogeneous material for each edge ring 15. The controller 30 may determine that an error has occurred in the plasma processing apparatus 10 when the time until the detection of a product caused by a heterogeneous material in the currently installed edge ring 15 is shorter than the past record or when the time is long. For example, if there is a bias in the plasma generated in the plasma generation region P, abnormal consumption will occur, and the time until detecting a product caused by a heterogeneous material becomes shorter than the time in the past records. In this case, the consumed edge ring 15 may be maintained, and additional operations may be performed to prevent abnormalities (e.g., plasma bias) in the plasma processing apparatus 10.

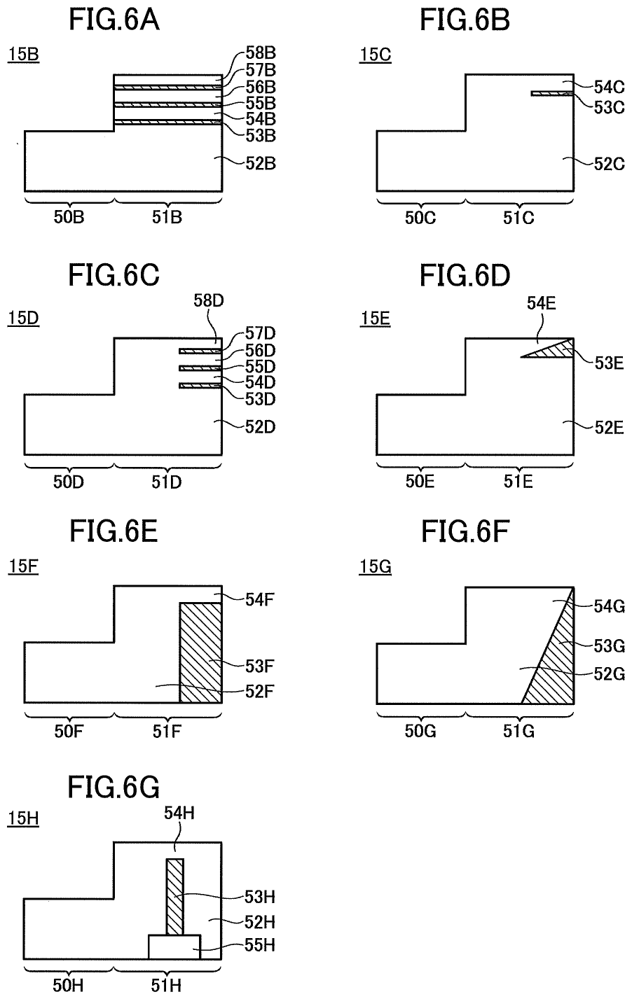

Next, another example of an edge ring 15 included in the plasma processing apparatus 10 according to one embodiment will be described with reference to FIGS. 6A to 6G. FIGS. 6A to 6G are one-sided cross-sectional views of edge rings 15B to 15H according to yet another example.

The edge ring 15B illustrated in FIG. 6A differs from the edge ring 15 shown in FIG. 2A in that the marker layer has multiple layers (three layers). The edge ring 15B has an inner ring portion 50B and an outer ring portion 51B. The outer ring portion 51B has a base part 52B, a marker layer 53B, an intermediate layer 54B, a marker layer 55B, an intermediate layer 56B, a marker layer 57B, and an upper layer 58B. The base part 52B is integrally formed with the inner ring portion 50B. The marker layer 53B is formed over the base part 52B. The intermediate layer 54B is formed over the marker layer 53B. The marker layer 55B is formed over the intermediate layer 54B. The intermediate layer 56B is formed over the marker layer 55B. The marker layer 57B is formed over the intermediate layer 56B. The upper layer 58B is formed over the marker layer 57B. The inner ring portion 50B, the base part 52B, the intermediate layer 54B, 56B, and the upper layer 58B are formed of silicon, for example. The marker layers 53B, 55B, 57B are formed of a heterogeneous material (e.g., tungsten) different from silicon.

With this arrangement, the detection result of the detector 40 at the edge ring 15B repeats detection and non-detection as the consumption progresses on the top surface of the outer ring portion 51B. By counting the number of repetitions, the degree of the consumption of the edge ring 15B can be detected.

Further, the processing may be changed according to the detection result of the detected value. For example, if the detector 40 detects the first heterogeneous material, then the marker layer 57B is determined to be exposed. In this case, the controller 30 raises the edge ring 15B by an amount equivalent to the consumed thickness of the edge ring 15B through an elevator (not shown in the drawing) for raising and lowering the edge ring 15B. When the detector 40 is a heterogeneous material for the second time, it is determined that the marker layer 55B is exposed. In this case, the controller 30 applies a voltage to the edge ring 15B through a voltage applying portion (not shown in the drawing) that applies a DC voltage to the edge ring 15B. This allows the sheath on the wafer W and the sheath on the edge ring 15B to be flat, while returning the incident angle of ions on the wafer W to a state prior to the edge ring 15B being consumed. In addition, when the detector 40 detects a heterogeneous material three times, it is determined that the marker layer 53B is exposed. In this case, the controller 30 may determine that the edge ring 15 should be replaced.

The edge ring 15C illustrated in FIG. 6B differs from the edge ring 15 illustrated in FIG. 2A in that a marker layer is provided on the outer peripheral side. The edge ring 15C has an inner ring portion 50C and an outer ring portion 51C. The outer ring portion 51C has a base part 52C, a marker layer 53C and an upper layer 54C.

The edge ring 15D illustrated in FIG. 6C differs from the edge ring 15B illustrated in FIG. 6A in that a marker layer is provided on the outer peripheral side. The edge ring 15D has an inner ring portion 50D and an outer ring portion 51D. The outer ring portion 51D has a base part 52D, a marker layer 53D, an intermediate layer 54D, a marker layer 55D, an intermediate layer 56D, a marker layer 57D, and an upper layer 58D.

The edge ring 15E illustrated in FIG. 6D differs from the edge ring 15A illustrated in FIG. 4A in that a marker layer is provided on the outer peripheral side. The edge ring 15E has an inner ring 50E and an outer ring 51E. The outer ring portion 51E has a substrate 52E, a marker layer 53E and an upper layer 54E. The marker layer 53E is formed so as to widen horizontally from the top surface of the outer ring portion 51E in a depth direction.

According to the edge rings 15C to 15E shown in FIGS. 6B to 6D, the positions where products are generated from heterogeneous materials can be moved away from the wafer W. This reduces the influence of the products (gases) caused by the heterogeneous materials on the wafer W processing.

The edge ring 15F illustrated in FIG. 6E differs from the edge ring 15 illustrated in FIG. 2A in that a marker layer is provided on the outer peripheral side. A marker layer 53F is formed to the bottom surface of the outer ring portion 51F.

The edge ring 15G illustrated in FIG. 6F differs from the edge ring 15A illustrated in FIG. 4A in that a marker layer is provided on the outer peripheral side. A marker layer 53G is formed on the bottom surface of the outer ring portion 51G.

An edge ring 15H illustrated in FIG. 6G differs from the edge ring 15 illustrated in FIG. 2A in that a marker layer is embedded inside the outer ring portion 51. The edge ring 15H has an inner ring portion 50H and an outer ring portion 51H. The outer ring portion 51H has a base part 52HH, a marker layer 53H, an upper layer 54H, and an embedded portion 55H. A bottom hole is formed from the bottom surface of the outer ring portion 51H, and a marker layer 53H is formed by embedding a heterogeneous material in the hole. Further, the bottom surface of the outer ring portion 51H is embedded with an embedded portion 55H made of silicon.

According to the edge rings 15F to 15H illustrated in FIGS. 6E to 6G, machining can be performed as compared to forming films of different materials, thereby reducing processing costs.

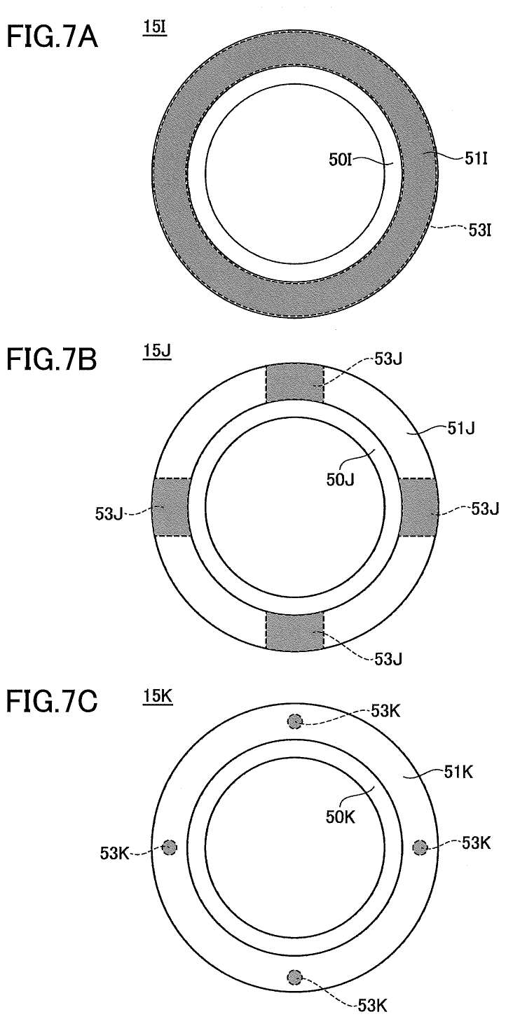

FIGS. 7A to 7C are examples of a plan view of an edge ring. Here, the marker layer is not exposed on the top surface of the outer ring portion of the edge ring. For this reason, the marker layer is illustrated with a hidden line (dashed line) and highlighted with a shaded line to clarify the position.

As illustrated in FIG. 7A, an edge ring 15I has an inner ring portion 50I and an outer ring portion 51I. The marker layer 53I may be provided around the full circumference. The cross-sectional shape may be the same as the shapes of the edge ring 15 illustrated in FIG. 2A, the edge ring 15A illustrated in FIG. 4A, or the edge ring 15B illustrated in FIG. 6A. In the radial direction, the edges rings 15C to 15G illustrated in FIGS. 6B to 6F may be disposed on the outer circumferential side.

As illustrated in FIG. 7B, the edge ring 15J has an inner ring portion 50J and an outer ring portion 51J. Four marker layers 53J may be provided at equally spaced intervals of every 90 degrees in the circumferential direction. It is not limited to the circumferential direction that is provided at equal intervals at predetermined angles, but may be provided at non-equally spaced intervals. Further, the number of the marker layers 53J is not limited to four, but may be one or more. The cross-sectional shape may be the same as the shapes of the edge ring 15 illustrated in FIG. 2A, the edge ring 15A illustrated in FIG. 4A, or the edge ring 15B illustrated in FIG. 6A. In the radial direction, the edge rings 15C to 15G illustrated in FIGS. 6B to 6F may be disposed on the outer circumferential side. In the radial direction, as illustrated in FIG. 6B, it may be disposed on the outer circumferential side.

As illustrated in FIG. 1C, the edge ring 15K has an inner ring portion 50K and an outer ring portion 51K. Four marker layers 53K may be provided at equal intervals at predetermined angles in the circumferential direction. In the circumferential direction, the spaces are not limited to equally spaced distances, but may be unequally spaced. Further, the number of the marker layers 53K is not limited to four, but may be one or more. The cross-sectional shape may be the same as the shape in the edge ring 15H illustrated in FIG. 6G.

If multiple marker layers are provided in the thickness direction, as illustrated in FIGS. 6A and 6C, the heterogeneous material may be changed for each marker layer. This makes it possible to reliably detect the etch progress.

Alternatively, heterologous materials may be changed for each marker layer when multiple marker layers are provided circumferentially, as illustrated in FIGS. 7B and 7C. This allows for detection of etching bias.

As discussed above, according to the embodiments, an annular member, a substrate processing apparatus, and a method of controlling a substrate processing apparatus capable of detecting wear can be provided.

Although the embodiments of the plasma processing apparatus 10 have been described above, the present disclosure is not limited to the above-described embodiments, and various modifications and modifications can be made within the scope of the gist of the present disclosure as claimed.

All examples recited herein are intended for pedagogical purposes to aid the reader in understanding the disclosure and the concepts contributed by the inventor to furthering the art, and are to be construed as being without limitation to such specifically recited examples and conditions, nor does the organization of such examples in the specification relate to a showing of the superiority or inferiority of the disclosure. Although the embodiments of the present disclosure have been described in detail, it should be understood that various changes, substitutions, and alterations could be made hereto without departing from the spirit and scope of the disclosure.

What is claimed is:

1. An annular member, comprising:
an annular member body to be disposed around a substrate in a substrate processing apparatus; and
a heterogeneous material portion disposed in the annular member body and formed of a heterogeneous material different from a material of the annular member body.

2. The annular member as claimed in claim 1, wherein the heterogeneous material portion is disposed on an outer circumferential side of the annular member body.

3. The annular member body as claimed in claim 1, wherein the heterogeneous material portion is formed so as to increase a horizontal width from a top surface toward a bottom surface of the annular member body.

4. The annular member body as claimed in claim 1, wherein the annular member body includes a plurality of layers of the heterogeneous material portion in a vertical direction.

5. The annular member as claimed in claim 1, wherein the heterogeneous material portion is entirely provided in a circumferential direction of the annular member body.

6. The annular member as claimed in claim 1, wherein the heterogeneous material portion is partially provided in a circumferential direction of the annular member.

7. The annular member as claimed in claim 1, wherein a first product produced in etching the heterogeneous material differs from a second product produced in etching the annular member body.

8. A substrate processing apparatus, comprising:
an annular member to be disposed around a substrate in a substrate processing apparatus;
a heterogeneous material portion disposed in the annular member and formed of a heterogeneous material different from a material of the annular member; and
a detector configured to detect a product produced in etching the heterogeneous material.

9. The substrate processing apparatus as claimed in claim 8, further comprising:
a controller configured to control a consumption state of the annular member based on a detected value of the detector.

10. A method of controlling a substrate processing apparatus, the substrate processing apparatus including:
an annular member to be disposed around a substrate in a substrate processing apparatus;
a heterogeneous material portion disposed in the annular member and formed of a heterogeneous material different from a material of the annular member; and
a detector configured to detect a product produced in etching the heterogeneous material, the method comprising a step of:
determining a consumption state of the annular member based on a detection value of the detector.
